(19) United States
(12) Patent Application Publication
(10) Pub. No.: US 2014/0253172 A1
(43) Pub. Date: Sep. 11, 2014

(54) Emergency Power System Environmental Alert Module

(71) Applicant: Regal Beloit Canada, an Alberta Limited Partnershi, Langley (CA)

(72) Inventor: Jitendra [Jit] Roop, Delta (CA)

(21) Appl. No.: 13/792,500

(22) Filed: Mar. 11, 2013

(51) Int. Cl. G01R 31/40

(52) U.S. Cl. CPC G01R 31/40
USPC 324/764.01

(57) ABSTRACT

There is provided an apparatus and method to alert an operator of an emergency power system of an anomaly detected in an emergency power system prior to a severe environmental event based on receipt of an alert. The emergency power system environmental alert module is installed in the emergency power system and is coupled to an emergency power source and a main power source. When a public alerting service issues an alert of an impending environmental occurrence, such as an earthquake, hurricane, tornado, the environmental alert module of the emergency power system automatically performs tests and provides data reports to the operator or user of the emergency power system.

### FIELD OF THE INVENTION

The present invention relates to the field of industrial automation and control, particularly to a system and method for an Emergency Power Control

System to monitor/conduct tests and relay status information of one of a generator control system and an automatic transfer switch initiated via advanced notification of environmental events.

### BACKGROUND OF THE INVENTION

Generator Controls Systems (GCS) or Paralleling Switchgear (PSG) and/or Automatic Transfer Switches (ATS) are used where emergency backup power is legally required or optionally desired, such as Hospitals, Data Centers, Waste Water Treatment Plants, High Rise buildings, and Elderly Care Facilities. Also in some circumstances the GCS or ATS is used within factories and residential homes.

The National Electrical Code chapter 7 covers Emergency and standby power systems. Articles 700, 701, and 702. Article 700 addresses emergency standby systems, Article 701 addresses legally required standby systems, and Article 702 addresses optional standby systems.

The apparatus of the present disclosure must also be of construction which is both durable and long lasting, and it should also require little or no maintenance to be provided by the user throughout its operating lifetime. In order to enhance the market appeal of the apparatus of the present disclosure, it should also be of inexpensive construction to thereby afford it the broadest possible market. Finally, it is also an objective that all of the aforesaid advantages and objectives be achieved without incurring any substantial relative disadvantage.

### SUMMARY OF THE INVENTION

It is provided an apparatus and method to monitor and receive severe environmental reports for a specific location that emergency equipment is located. A controller on the emergency power equipment would monitor alerts from various alerting protocols over the Internet protocol such as from FEMA or the National Weather Service or the National Oceanic and Atmospheric Administration. An environmental alert module registers and is configured to control emergency power system through a private network or through a commercial mobile alert service configured to receive alerts and initiate tests and report status of the emergency electrical equipment. The disclosed environmental alert module proactively and automatically performs a test of the emergency equipment such as an automatic transfer switch system or a generator control system based on severe weather and environmental alerts provides a status report and notification to the operator of the systems via e-mail, tweets, or other messaging services. In addition, the operator or user of the system can log into the system to request further remote tests or status reports. Based on the input signals and configuration, the automatic tests and the status reports on the emergency equipment.

An emergency power system environmental alert module for an emergency power system is disclosed. The emergency power system, is coupled to a main power source and an emergency power source. The emergency power system environmental alert module includes a receiver module, a test module, and a transmitter module.

The receiver module is tuned to receive an environmental alert report from one of several alert reporting agencies. A test module includes a test element configured to test one of the generator controls of a generator control system and an automatic transfer switch system. There is at least one additional test element configured to test one of the generator control system and the automatic transfer switch system. It should be understood in any number of test elements (N) can be configured on the environmental alert module as determined by a user or operator of the system.

The test module is coupled to each of the test elements, with the emergency power system, and the receiver module. The test module is configured to test predetermined emergency power system components based on the at least one environmental alert report received by the receiver module.

The transmitter module is coupled to the test module. The transmitter module is configured to communicate with an operator of the emergency power system and provide emergency power system status data and related alert report when data from at least one of the test elements detects and anomaly, with the emergency power system environmental alert module coupled to one of the generator control system and automatic transfer switch system.

In another embodiment, the environmental alert report is received by one of a common alert protocol, a commercial mobile service alert protocol, and a private alert protocol. The alert protocols can be one of a group consisting of a State alerting authority alert, a local alerting authority alert, a national weather service alert, an integrated public alert warning system alert, a federal emergency management agency alert, and an international alerting protocol.

It is further provided an emergency power system environmental alert module for an emergency power system. The emergency power system includes at least one of a generator control system and an automatic transfer switch. The emergency power system is coupled to an emergency power source and through a main power source.

The emergency power system environmental alert module includes a receiver module tuned to receive an environmental alert report. A test module is coupled to a test element configured to test one of the generator control system and automatic transfer switch system and includes at least one additional test element configured to test one of the generator control system and automatic transfer switch system. The test module is coupled to each of the test elements, to the emergency power system and a receiver module. A test module is configured to test predetermined emergency power system components based on the at least one environmental alert report received by the receiver module.

A transmitter module is coupled to the test module, with the transmitter module configured to communicate with an operator of the emergency power system and provide emergency power system status data and related alert reports when data from at least one of the test elements detects an anomaly.

The apparatus of the present invention is of a construction which is both durable and long lasting, and which will require little or no maintenance to be provided by the user throughout its operating lifetime. Finally, all of the aforesaid advantages and objectives are achieved without incurring any substantial relative disadvantage.

### DESCRIPTION OF THE DRAWINGS

These and other advantages of the present disclosure are best understood with reference to the drawings, in which:

FIGS. 1A-1C are schematic illustrations of alert protocols for an emergency power system in accord with this disclosure for one of a common alert protocol, a private alert protocol, and a commercial mobile alert protocol;

FIG. 2 is a connection diagram for a typical Generator Control System (GCS);

FIG. 3 is a connection diagram for a typical Automatic Transfer Switch (ATS);

FIG. 4 is a flow diagram of a typical automatic transfer switch;

FIG. 5 is a flow diagram of a typical multi-generator control system;

FIG. 6 is a schematic illustration of an exemplary embodiment of the emergency power system illustrated in each of FIGS. 1A-1C, including an emergency power system environmental alert module in accord with this disclosure;

FIG. 7 is a flow diagram of an exemplary embodiment for an environmental alert test and status functionality of the environmental alert module illustrated in FIG. 6;

FIG. 8 is a flow diagram of the automatic transfer switch illustrated in FIG. 4 including the environmental alert test and status functionality illustrated in FIG. 7 of the environmental alert module;

FIG. 9 is a flow diagram of the multi-generator control system illustrated in FIG. 5 including the environmental alert test and status functionality illustrated in FIG. 7 of the environmental alert module.

### DETAILED DESCRIPTION OF THE EXEMPLARY EMBODIMENTS

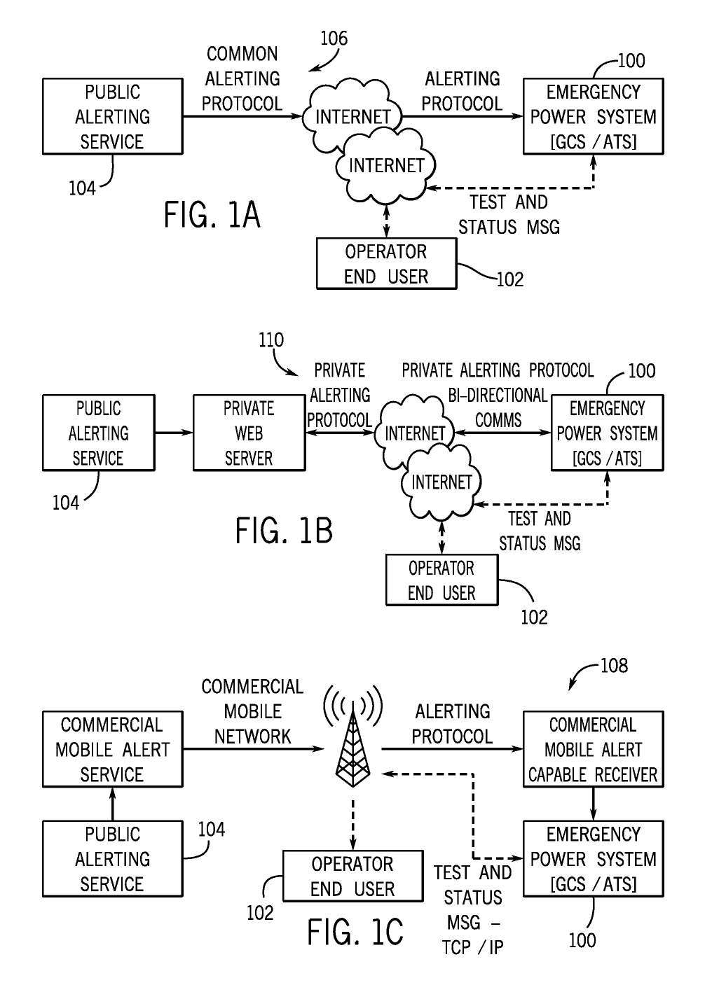

Referring to the FIGS. 1-9, there is disclosed an emergency power system 100 environmental alert module 140 (hereinafter “alert Module”) configured to perform a test of emergency power equipment such as an automatic transfer switch system 121 or a generator control system 113 based on severe weather/environmental alerts. The alert module 140 further provides notifications to the operator of the various systems via several means, for example an e-mail, a tweet, or other messaging services.

The apparatus and methods disclosed herein, monitor and receive severe environmental reports for the specific location the emergency equipment, i.e., ATS or GCS, is located. A controller on the emergency power equipment monitors alerts from various alerting protocols 106, 108, 110 over a national Internet protocol such as from Federal Emergency Management Agency (FEMA), IPAWS, National Weather Service, National Oceanic and Atmospheric Agency (NOAA), etc. The emergency power equipment control system typically is also registered and configured with a private network that can be local governmental, commercial, or residential, with the system configured to receive alerts and initiate test and report status of the emergency power equipment coupled to the ATS or GCS.

As disclosed herein, the emergency power system 100 environmental alert module 140 proactively and automatically performs a predetermined test of the emergency equipment based on the severity of weather, environmental alerts, or related conditions and provides a status report and notification to the operator of the system by convenient messaging services. Upon receipt of the status report and/or alerts, the operator of the system can log into the system remotely and request to perform remote tests in addition to the predetermined test configured in the controller. Based upon the input signals and configuration, the automatic test and status reports provide configuration data, such as for example timing, set points, etc. and the status of the equipment such as for example fuel level, estimated run time, oil, coolant levels, temperature of the equipment and timing when certain events occur, such as emergency power transfer from a line system to the backup system.

The apparatus and method disclosed herein mitigate the emergency power system 100 downtime by pretesting the system prior to the arrival of severe environmental conditions, such as a tornado, a hurricane, earthquake, etc. Automated tests based on predetermined criteria, the severity of the environmental alert, and estimated duration are performed. Status report messages are transmitted to an operator with the operator able to perform additional tests before the event for which the alert was received occurs.

The emergency power system 100 and environmental alert module 140 will provide an end user or an operator with information relative to the condition of the specific emergency power equipment prior to a severe environmental condition such as a hurricane, storm, flood, tornado, earthquake, etc. and assist in prioritizing an action plan. For example, in a multi-site location, if one site indicated a low fuel level and an environmental alert was for a sustained hurricane, the operator could proactively stock up on fuel for that particular site. The operator would not have to wait until the hurricane occurred to deal with the low fuel condition. In another example, in a residential automatic transfer switch system 120, upon receipt of and an environmental alert, the alert module system 140 would perform a no load test and send a status report to a homeowner. The owner would be able to react according to the status message such as that the system was okay thereby providing a certain comfort level to the residential homeowner in an emergency situation. In another example, based on the severity of the environmental alert and status of the equipment, the emergency power equipment coupled to the emergency power system 100 environmental alert module 140 of the present disclosure would modify the priority of load shed to maximize longevity of emergency power system 100 operation.

FIGS. 1A, 1B, and 1C illustrate, systematically, several types of alert protocols used with emergency power systems such as an automatic transfer switch system 120, and/or a generator control system 112.

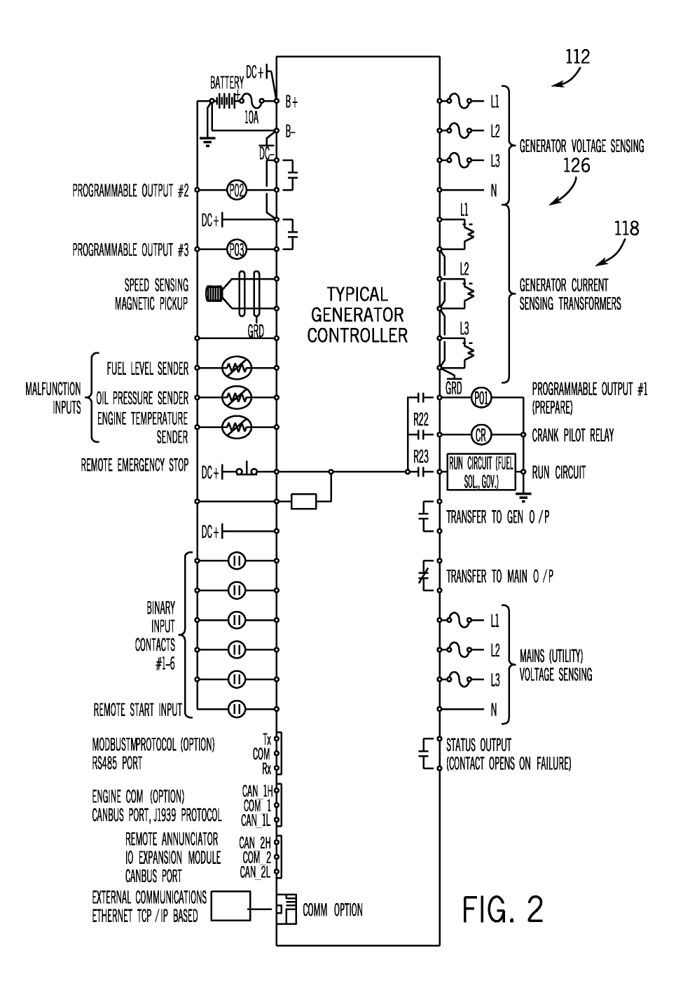

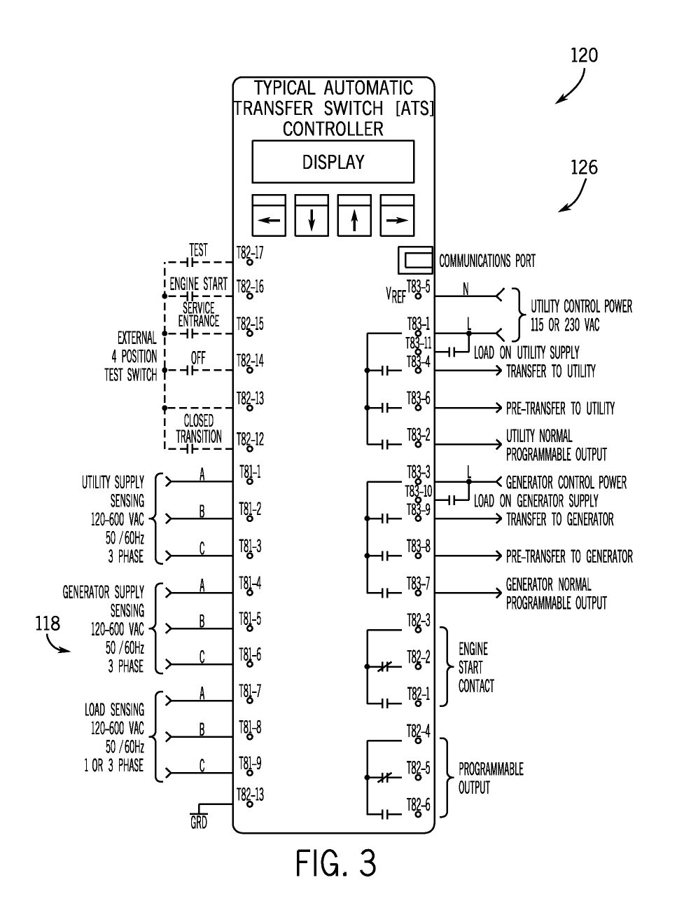

The emergency power system 100 typically consists of a generator control system 112 as illustrated in FIG. 2 and also in an automatic transfer switch 120 system as illustrated in FIG. 3. FIGS. 2 and 3 illustrate the various equipment connections in a typical controller of an emergency power system 100.

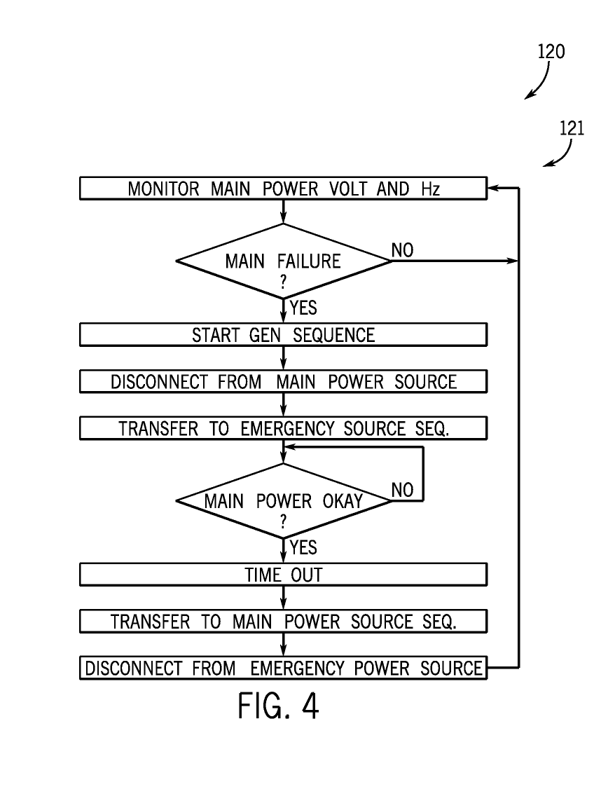

Referring to FIG. 4 there is illustrated a flow chart for a typical automatic transfer switch system functionality 121. Initially the system is in an auto-standby configuration configured to monitor the main power source 128, for example from the local utility, and transfer to an emergency power source 114, for example a motor-generator set, upon failure of the main power source 128. As illustrated in the flow chart, the emergency power system 100 monitors the main power source 128, typically the voltages and frequency of each phase of a system and if the voltage and/or frequency fall below a predetermined threshold, the controller will start an emergency power source 114, typically a backup generator. The system monitors the voltage and frequency on the emergency source as it comes up to predetermined thresholds for operation and then transfers the load to the emergency power source 114. With the emergency power system connected, the controller then disconnects the main power source. The emergency power system monitors the main power source and upon return to its appropriate voltages and frequencies, confirms that the emergency power system voltage and frequency are in-sync with the main power voltage and frequency and then transfers the load back to the main power source. The system then shuts down the emergency power system and resets to monitor the main power source.

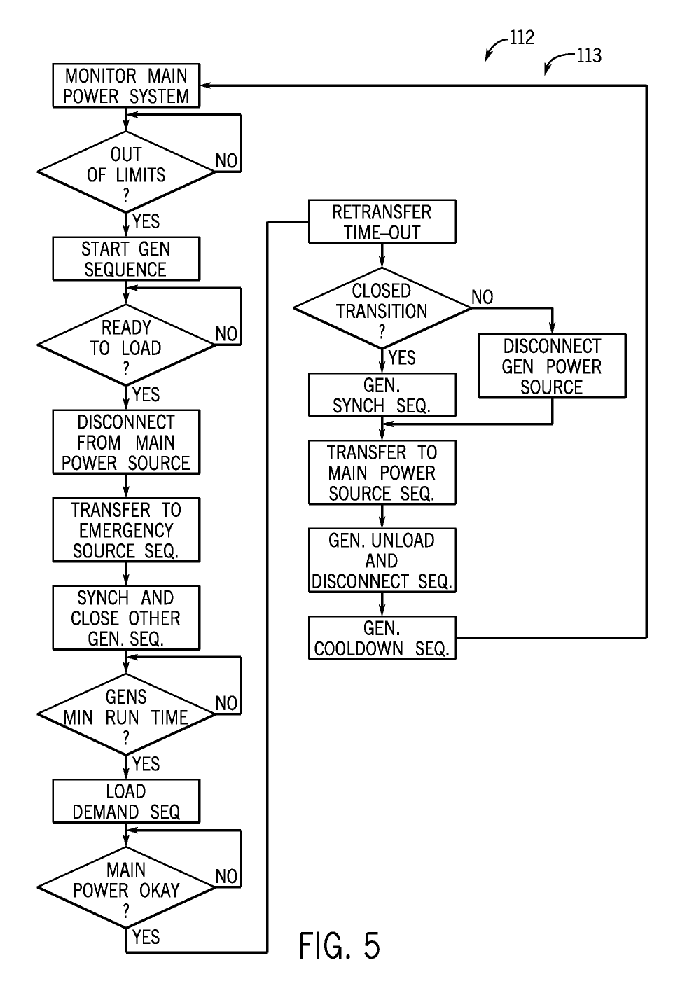

As illustrated in FIG. 5, a typical multi-generator control system functionality performs similar monitoring and actions as described above with respect to the automatic transfer switch system with the emergency power generators controlled depending on system load requirements. The generator control system can be for a single generator system or a multi-emergency power generator system all controlled by the control system illustrated in FIG. 5.

It should be noted that in some emergency standby systems, there are no mandatory in-field test requirements, however for legally required emergency power systems, there are specific periodic tests requirements. As described above, factories, data centers, and hospitals require modular distribution of emergency power system and it is important that they know the condition of the system prior to a severe environmental condition, such as a hurricane or a flood or a tornado, earthquake to ensure that the emergency power system is configured and operable for its intended purpose. As discussed above, the current systems do not provide a prior alert of a severe environmental condition.

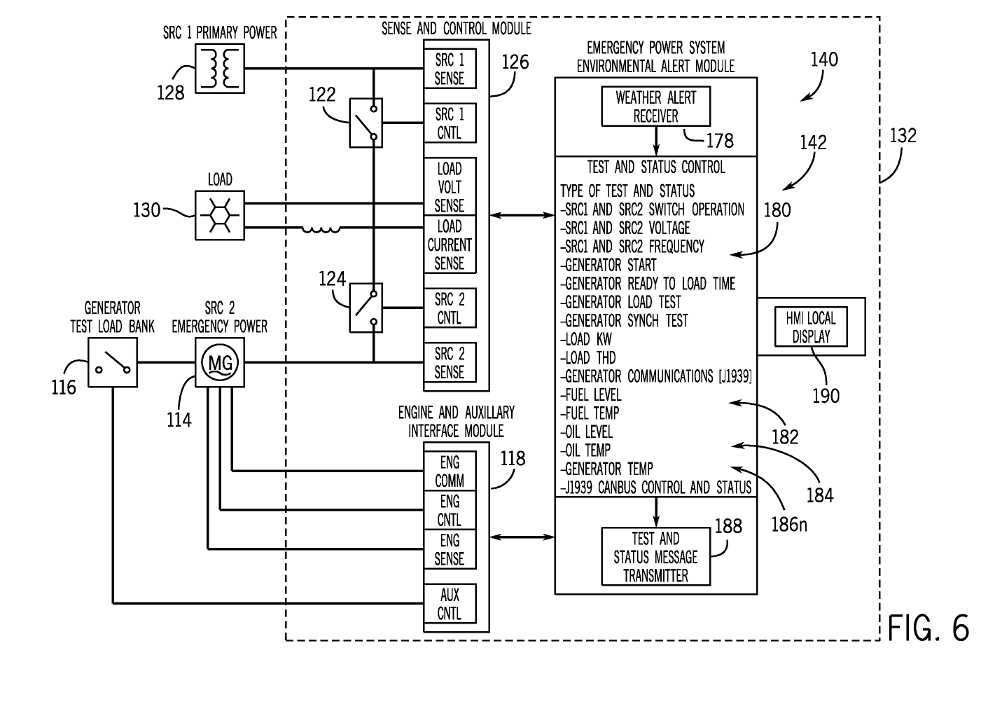

FIG. 6 is a schematic illustration of an exemplary embodiment of an emergency power system 100 illustrated in each of FIGS. 1A-1C, and includes an emergency power system environmental alert module 140 coupled to the controller modules 118, 126 of the load 130 and emergency power systems 114. It should be understood that the configuration is similar for a generator control system 112 and an automatic transfer switch system 120.

In a typical arrangement, the emergency power system controls are contained within a suitable panel box 132 represented by the dotted line box of FIG. 6. Appropriate sensors and controls monitor and control the load 130 and transfer to the emergency power system which is typically a motor generator 114. Circuitry for operation of the sensors and controls are contained on a sense and control module 126 within the panel box 132. In some situations an engine and auxiliary interphase module 118 is also coupled to the generator emergency power system which typically includes a generator test load bank 116. The sensing control interphase modules 118, 126 are coupled to an emergency power system environmental alert module 140 in accord with the present disclosure.

An emergency power system environmental alert module 140 is coupled to at least one of a generator control system 112 and an automatic transfer switch system 120. The emergency power system environmental alert module 140 is also coupled to the emergency power source 114, with the emergency power system 114 coupled to a main power source 128. The emergency power system environmental alert module 140 includes a receiver module 178, a test module 180, and a transmitter module 188.

The receiver module 178 is tuned to receive an environmental alert report from one of the agencies mentioned above. The receiver module 178 is configured to receive the environmental alert report by radio transmission, a Wi-Fi system or a hard wire arrangement or any combination of such systems.

The transmitter module 188 is coupled to the test module 180 with the transmitter module 188 configured to communicate with an operator of the emergency power system and provide emergency power status data and related alert reports when data from the test module indicates an anomaly in the primary power source 128. The transmitter 188 is configured to provide the communication to an operator by radio transmission, Wi-Fi system, or a hard wire system.

A test module 180 is coupled to each of the emergency power system control and sensor modules 118, 126, the receiver module 178, and the transmitter module 188. A test element 182 is configured to test one of the generator control system 112 and automatic transfer switch 120 components. At least one additional test element 184 is configured to test one of the generator control systems 112 and automatic transfer switch 120 components. Each of the test elements is coupled to the test module 180 with the test module 180 configured to test predetermined emergency power system components based on the at least one environmental alert report received by the receiver module 178.

The emergency power system environmental alert module 140 receives the environmental alert report via one of a common alert protocol 106, a commercial mobile service alert protocol 108, and a private alert protocol 110. Such alert protocols typically are one of a group consisting of a State alerting authority alert, a local alerting authority alert, a national weather service alert, an integrated public alert warning system alert, and a federal emergency management agency alert or an international alerting protocol.

Upon receipt of the environmental alert from one of the above identified agencies or alert protocols, the emergency power system environmental alert module 140 performs predetermined tests on the system components. A status report and data generated by the test are transmitted to an operator for evaluation. The operator can request additional remote tests of the system components and additional status reports.

If the emergency power system environmental alert module 140 detects an anomaly, for example a voltage drop below a predetermined value, in the main power source 128, a switch is made to the emergency back-up power system 114 in either the automatic transfer switch system or the generator control system as described above. A first switch 122 and a second switch 124 are coupled to each of the main power source 128, the emergency power source 114 and the source and control module 126. (See FIG. 6)

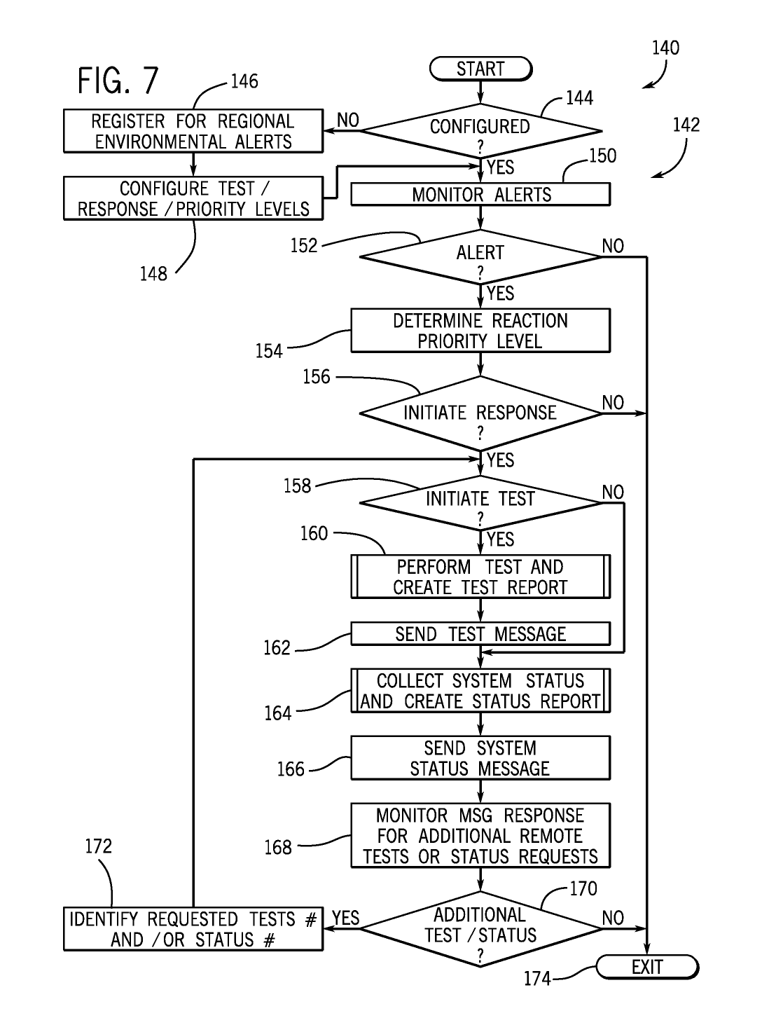

FIG. 7 is a flow diagram of an exemplary embodiment of an environmental alert test and status functionality of the environmental alert module contained in the equipment illustrated in FIG. 6.

The emergency power system controller as illustrated in FIG. 6 is modified when it is coupled to the emergency power system environmental alert module 140 described herein. When installing the emergency alert module 140 in the emergency power system control box 132, the end user operator configures the controller, with the human/machine interface (HMI) 190, to respond to certain environmental alert parameters and sets the appropriate action, such as a test, or status report, and in some cases both test and status reports. The HMI 190 can be a microprocessor, smart phone or other suitable communication and programming device.

When an environmental alert is issued, the controller coupled to the environmental alert module parses the alert message to determine the message type, scope, category, urgency, severity, certainty, location, and a geographic code among other parameters. If the environmental alert received by the receiver module 178 matches the configured requirements in the emergency alert module 140, the controller will execute predefined actions as configured in the test and status control module 142 and send a status message, through the transmitter module 188 to the end user or operator. The end user or operator is able to respond to the message remotely through a human machine interphase (HMI) coupled to the environmental alert module 140 to request additional remote tests and/or status reports.

FIG. 7 illustrates an exemplary embodiment of the test and status functions 142 of the emergency power system environmental alert module 140. At the start, the system confirms that the system has been configured. If yes, the system monitors alert through the receiver module. During the installation and commissioning process the end user or operator will configure the environmental alert module 140, for example, as set forth in the chart below.

| | STEP |
|---|---|
| DESCRIPTION | REFERENCE |
| Confirm if the system has been configured | 144 |
| [configuration bit set]. If not then call | |
| Configuration wizard. | |
| During installation and commissioning | 146 |
| process the Installer or Operator will | |
| configure the Emergency Power System | |
| controller to receive and parse | |
| environmental alerts. The general | |
| parameters entered are [but not limited | |
| to]: | |
| Environmental Alert: Enable/Disable | 146 |
| Alert Protocol to decipher [i.e. CAO, | 146 |
| CAP-CP, RSS feeds, Private] | |
| Area/Location information [ZIP, SAME, | |
| FIPS, Geocode] to match alerts to | |
| equipment location | |
| Enable STATUS of Alert msg:- Actual | 146 |
| Alert, Update, Cancel | |
| Reaction Priority Level 1, 2, & 3 | 148 |
| [Function of Urgency level, and Severity | |
| level, and Certainty level]. Purpose is | |
| to initiate specific tests based on | |
| Reaction Priority Level. | |
| Equipment Tests 1, 2, & 3. Purpose is | 148 |
| to identify which test to execute based on | |
| Reaction Priority Level. | |
| Status Message configuration | 148 |
| parameters | |
| Response Address Configuration: | 148 |
| msg type, email address, sms address, IP | |
| Address, tweet access . . . etc. | |
| Equipment Status parameters to | 148 |
| include in status message. This is | |
| selectable from number of Inputs & Outputs | |
| available and Type [Analog or Digital or | |
| Communication]. Example: Breaker | |
| position, Oil Level, CANbus communications | |
| status, Fuel Level, Temperature [ambient, | |
| and equipment . . . etc] | |
| Assign Tests to Test # for remote test | 148 |
| requests | |
| Assign Status # to status type for | 148 |
| remote status requests | |
| Monitor for alerts, and parse messages | 150 |
| Determine if an Alert is for the current | 152 |
| location, if not the exit, else process | |
| next step. | |
| Determine the Reaction Priority Level | 154 |
| based on severity, urgency and certainty | |
| Based on Reaction Priority Level determine | 156 |
| if a response is required. If no response | |
| is required then exit | |
| If a response is required, then determine | 158 |
| if there is a test associated with the | |
| response & status message | |
| If no TEST is required but only a Status | 156, 158, |
| Message response is required then collect | & 164 |
| Status of equipment [as per configuration] | |
| and send current Status message. | |
| Else the Reaction Priority Level requires | 158 |
| a Test | |
| Initiate the test [as per configuration] | 160 & 162 |
| and send test results. | |
| Collect System Status and send system | 164 & 166 |
| status message to predefined address. | |
| Monitor for additional Test or Status | 168 |
| requests. | |
| If additional Tests or Status requests are | 170 & 172 |
| received then store the Test # and Status | |
| # and execute test and status as per | |
| configuration and send response. | |
| If no further remote requests are received | 170 & 174 |
| then continue to monitor for next Alert | |
| message. | |

The test elements 182, 184, 186 (N) configured to test components of the generator control system or the automatic transfer switch system are illustrated in FIG. 6 in the test and status control box 180. It should be understood that these are exemplary test elements and there may be additional test elements as determined by the end user or operator of the emergency power system environmental alert module 140. Various test elements can be based on sensors in the sense and control modules 126 or in the engine and auxiliary interphase module 118 illustrated in FIG. 6 with the end user or operator configuring the test elements to be performed automatically or upon demand.

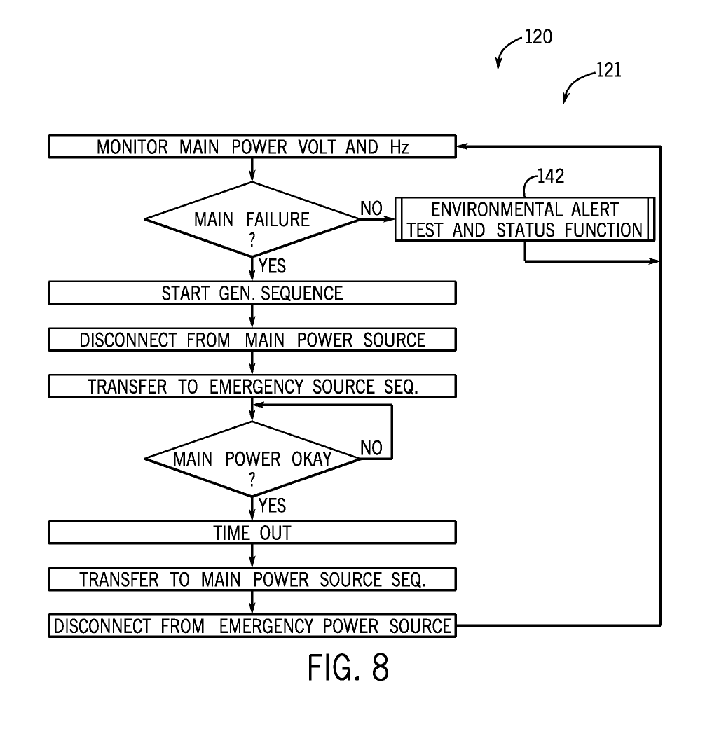

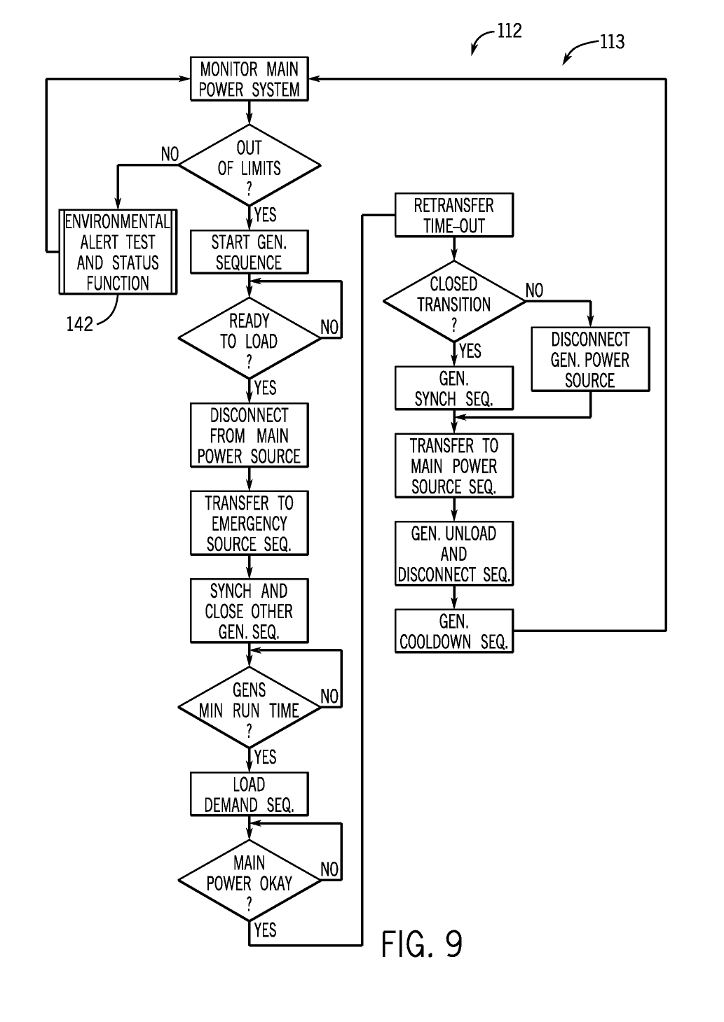

FIG. 8 illustrates the automatic transfer switch 120 functionality including the environmental alert test and status functions 142 of the environmental alert module 140 of the present disclosure. FIG. 9 is a flow diagram of an environmental alert test and status functionality 142 of environmental alert module 140 for the generator control system 112.

With either an automatic transfer switch system 120 or a generator control system 112 configured with the environmental alert module 140 of the present disclosure, an end user or operator would be provided with information before an environmental event associated with the public emergency alert protocol rather than waiting until such environmental event occurs.

For purposes of this disclosure, the term “coupled” means the joining of two components (electrical or mechanical) directly or indirectly to one another. Such joining may be stationary in nature or moveable in nature. Such joining may be achieved with the two components (electrical or mechanical) and any additional intermediate members being integrally formed as a single unitary body with one another or the two components and any additional member being attached to one another. Such adjoining may be permanent in nature or alternatively be removable or releasable in nature.

Although the foregoing description of the present mechanism has been shown and described with reference to particular embodiments and applications thereof, it has been presented for purposes of illustration and description and is not intended to be exhaustive or to limit the disclosure to the particular embodiments and applications disclosed. It will be apparent to those having ordinary skill in the art that a number of changes, modifications, variations, or alterations to the mechanism as described herein may be made, none of which depart from the spirit or scope of the present disclosure. The particular embodiments and applications were chosen and described to provide the best illustration of the principles of the mechanism and its practical application to thereby enable one of ordinary skill in the art to utilize the disclosure in various embodiments and with various modifications as are suited to the particular use contemplated. All such changes, modifications, variations, and alterations should therefore be seen as being within the scope of the present disclosure as determined by the appended claims when interpreted in accordance with the breadth to which they are fairly, legally, and equitably entitled.

What is claimed is:

1. An emergency power system environmental alert module for an emergency power system, emergency power system with the emergency power system coupled to a main power source and an emergency power source, the emergency power system environmental alert module comprising:
a receiver module tuned to receive an environmental alert report;
a test element configured to test one of a generator control system and an automatic transfer switch;
at least one additional test element configured to test one of the generator control system and the automatic transfer switch;
a test module coupled to each of the test elements, to the emergency power system, and the receiver module, the test module configured to test predetermined emergency power system components based on the at least one environmental alert report received by the receiver module; and
a transmitter module coupled to the test module, the transmitter module configured to communicate with an operator of the emergency power system and provide emergency power system status data and related alert reports when data from at least one of the test elements detects an anomaly, with the emergency power system environmental alert module coupled to one of the generator control system and the automatic transfer switch.

2. The emergency power system environmental alert module of claim 1, wherein the environmental alert report is received an alert protocol via one of a common alert protocol, a commercial mobile service alert protocol, and a private alert protocol.

3. The emergency power system environmental alert module of claim 2, wherein the alert protocol for the environmental alert report is one of a group consisting of a State alerting authority alert, a local alerting authority alert, a National Weather Service alert, an Integrated Public Alert Warning System alert, a Federal Emergency Management Agency alert, and an International alerting Protocol.

4. The emergency power system environmental alert module of claim 1, further comprising the operator requesting one of an additional remote test of the emergency power system components and an additional status report.

5. The emergency power system environmental alert module of claim 1, wherein the emergency power system environmental alert module operates one of the generator control system and the automatic transfer switch if no anomaly is detected in the predetermined emergency power system components.

6. An emergency power system environmental alert module for an emergency power system, emergency power system includes at least one of a generator control system and an automatic transfer switch, and an emergency power source, with the emergency power system coupled to a main power source, the emergency power system environmental alert module comprising:
a receiver module tuned to receive an environmental alert report;
a test element configured to test one of the generator control system and the automatic transfer switch;
at least one additional test element configured to test one of the generator control system and the automatic transfer switch;
a test module coupled to each of the test elements, to the emergency power system, and the receiver module, the test module configured to test predetermined emergency power system components based on the at least one environmental alert report received by the receiver module; and
a transmitter module coupled to the test module, the transmitter module configured to communicate with an operator of the emergency power system and provide emergency power system status data and related alert reports when data from at least one of the test elements detects an anomaly.

7. The emergency power system environmental alert module of claim 6, wherein the environmental alert report is received an alert protocol via one of a common alert protocol, a commercial mobile service alert protocol, and a private alert protocol.

8. The emergency power system environmental alert module of claim 7, wherein the alert protocol for the environmental alert report is one of a group consisting of a State alerting authority alert, a local alerting authority alert, a National Weather Service alert, an Integrated Public Alert Warning System alert, a Federal Emergency Management Agency alert, and an International alerting Protocol.

9. The emergency power system environmental alert module of claim 6, further comprising the operator requesting one of an additional remote test of the emergency power system components and an additional status report.

10. The emergency power system environmental alert module of claim 6, wherein the emergency power system environmental alert module operates one of the generator control system and the automatic transfer switch if no anomaly is detected in the predetermined emergency power system components.

11. A method to determine the status and functionality of an emergency power system prior to a severe environmental event in the predetermined location associated with a main power source coupled to a load, with the emergency power system configured to electrically connect to the load through an automatic transfer switch system and operated by a generator control system, the method comprising:
installing an emergency power system environmental alert module in a panel box containing a sensor and control module coupled to the main power source and the emergency power system;
coupling the environmental alert module to the sensor and control module;
monitoring a public alerting service with a receiver module configured on the environmental alert module;
performing, upon receipt of an alert of a severe environmental event, a predetermined test of components of the emergency power system with a test module, including a test element, configured on the environmental alert module; and
transmitting the result of the predetermined test and a status report to an end user with a transmitter module configured on the environmental alert module.

12. The method of claim 11, further comprising performing at least one additional test of components of the emergency power system with an additional test element configured on the environmental alert module.
